(19) United States
(12) Patent Application Publication
(10) Pub. No.: US 2013/0113348 A1
(43) Pub. Date: May 9, 2013

(54) RUGGEDIZED CASE FOR HAND-HELD ELECTRONIC DEVICE

(71) Applicant: Case-Mate, Inc., Tucker, GA (US)

(72) Inventors: Robert Brett HOLBEN, Roswell, GA (US); Vyasateja JYOTHIGOWDANAPURA, Atlanta, GA (US); Saumil Chetan MODY, Smyrna, GA (US)

(73) Assignee: CASE-MATE, INC., Tucker, GA (US)

(21) Appl. No.: 13/670,053

(22) Filed: Nov. 6, 2012

Related U.S. Application Data
(60) Provisional application No. 61/557,702, filed on Nov. 9, 2011.

(51) Int. Cl. H05K 5/03

(52) U.S. Cl. CPC H05K 5/03
USPC 312/223.1

(57) ABSTRACT

A ruggedized case having a main cover to be fitted closely over a hand-held electronic device is tub-shaped and is open on one side thereof for receiving the device therein. The main cover includes a rigid tub and resilient portions on the inside and outside of the tub. A substantially rigid screen protector is provided for protecting the display and is closely fitted over a front face of the hand-held electronic device and is closely fitted within the ruggedized main cover and held firmly therein. Thus, resilient material is placed closely against the hand-held electronic device, the rigid protective portion is closely against the inner soft cushioning, and an outer layer of soft cushioning material is closely against the rigid protective portion. The rigid protective panel is sandwiched between elements of soft, cushioning material. This composite, cushion-first construction provides superior protection against mechanical shock.

### CROSS-REFERENCE TO RELATED APPLICATION

This application claims the benefit of U.S. Provisional Patent Application Ser. No. 61/557,702, filed Nov. 9, 2011, the entirety of which is hereby incorporated herein by reference.

### TECHNICAL FIELD

The present invention relates generally to the field of protective cases, and more particularly to a protective case for a hand-held electronic device.

### SUMMARY OF THE INVENTION

In example embodiments, the present invention provides a ruggedized case for a hand-held electronic device of the type having a display screen. The ruggedized case includes a ruggedized main cover adapted to be fitted closely over the hand-held electronic device and to surround and protect the back, top side, bottom side, left side, and right side thereof. The ruggedized main cover is open on one side thereof for receiving the hand-held electronic device therein. A substantially rigid screen protector is provided for protecting the display screen of the hand-held electronic device, and is adapted to be closely fitted over a front face of the hand-held electronic device in a manner to overlay the display screen of the hand-held electronic device. Moreover, the substantially rigid screen protector is adapted to be closely fitted within the ruggedized cover and held firmly therein. The substantially rigid screen protector and the ruggedized main cover are configured and adapted such that the screen protector is to be first fitted over a front face of the hand-held electronic device in a manner to overlay the display screen of the hand-held electronic device and then the screen protector and the electronic device are closely fitted within the ruggedized cover.

Optionally, the substantially rigid screen protector includes a substantially rigid face panel and at least two substantially rigid side panels extending from and connected to the face panel. Also optionally, the substantially rigid screen protector can include a pair of resilient protective pads positioned on upper and lower portions of an outer surface of the substantially rigid face panel.

Preferably, the ruggedized main cover includes a rigid protective plate, a resilient outer shell, and inner cushioning molded at least partially through the rigid protective plate and contiguous with the resilient outer shell such that the substantially rigid protective plate is substantially completely covered on one side by the resilient outer shell and on an opposite side of the substantially rigid protective plate one or more portions of the resilient inner cushioning is/are positioned between the substantially rigid protective plate and the hand-held electronic device inserted therein to cushion the hand-held electronic device from the substantially rigid protective plate.

In another aspect, the invention comprises a ruggedized case for a hand-held electronic device of the type having a display screen, and includes a ruggedized cover adapted to be fitted closely over the hand-held electronic device and to surround and protect the back, top side, bottom side, left side, and right side thereof. Preferably, the ruggedized cover is open on one side thereof for receiving the hand-held electronic device therein, and includes a substantially rigid protective plate sandwiched between a resilient outer shell molded around the substantially rigid protective plate and a resilient inner cushioning. The resilient inner cushioning can be molded at least partially through the rigid protective plate and be contiguous with the resilient outer shell such that the substantially rigid protective plate is substantially completely covered on one side by the resilient outer shell and on an opposite side of the substantially rigid protective plate one or more portions of the resilient inner cushioning is/are positioned between the substantially rigid protective plate and the hand-held electronic device. The ruggedized case further includes a substantially rigid screen protector for protecting the display screen of the hand-held electronic device, the substantially rigid screen protector being adapted to be closely fitted over a front face of the hand-held electronic device in a manner to overlay the display screen of the hand-held electronic device. The substantially rigid screen protector is adapted to be closely fitted within the ruggedized cover and held firmly therein.

Optionally, the substantially rigid screen protector includes a substantially rigid face panel and at least two substantially rigid side panels extending from and connected to the face panel.

In another form, the present invention comprises a ruggedized case for a hand-held electronic device of the type having a display screen, with the ruggedized case comprising a ruggedized, cushioned main cover adapted to be fitted closely over the hand-held electronic device and to surround and protect the back, top side, bottom side, left side, and right side thereof. The ruggedized, cushioned cover is open on one side thereof for receiving the hand-held electronic device therein, and includes a substantially rigid protective plate sandwiched between a resilient outer shell and a resilient inner cushioning. A substantially rigid screen protector is provided for protecting the display screen of the hand-held electronic device, with the substantially rigid screen protector being adapted to be closely fitted over a front face of the hand-held electronic device in a manner to overlay the display screen of the hand-held electronic device. The substantially rigid screen protector is adapted to be closely fitted within the ruggedized cover and held firmly therein, and has a substantially rigid transparent panel. Optionally, the substantially rigid screen protector snaps into the ruggedized, cushioned main cover.

In yet another form, the present invention relates to a method of protecting a hand-held electronic device of the type having a display screen, with the method comprising the steps of: a. providing a substantially rigid screen protector and a ruggedized main cover; b. placing the substantially rigid screen protector over a front face of the hand-held electronic device in a manner to overlay the display screen to secure the substantially rigid screen protector over the front face of the hand-held electronic device; and c. placing the substantially rigid screen protector together with the hand-held electronic device within the ruggedized cover to secure them therewithin.

In yet another form the present invention comprises a ruggedized case having a ruggedized main cover adapted to be fitted closely over a hand-held electronic device and to surround and protect the back, top side, bottom side, left side, and right side thereof. The ruggedized main cover is substantially tub-shaped and is open on one side thereof for receiving the hand-held electronic device therein. The ruggedized main cover includes a substantially rigid back and four substantially rigid sides extending up from the back, with the ruggedized main cover further comprising a resilient portion. A substantially rigid screen protector is provided for protecting the display screen of the hand-held electronic device and is adapted to be closely fitted over a front face of the hand-held electronic device in a manner to overlay the display screen of the hand-held electronic device. Also, the substantially rigid screen protector is adapted to be closely fitted within the ruggedized main cover and held firmly therein, with the substantially rigid screen protector having a substantially rigid transparent panel and one or more resilient members adjacent an outer face of the transparent panel.

These and other aspects, features and advantages of the invention will be understood with reference to the drawing figures and detailed description herein, and will be realized by means of the various elements and combinations particularly pointed out in the appended claims. It is to be understood that both the foregoing general description and the following brief description of the drawings and detailed description of the invention are exemplary and explanatory of preferred embodiments of the invention, and are not restrictive of the invention, as claimed.

### BRIEF DESCRIPTION OF THE DRAWINGS

FIG. 1 is a perspective, exploded view of a ruggedized case for a hand-held electronic device according to an example embodiment of the present invention.

FIG. 2 is a perspective, exploded view of a front portion of the ruggedized case of FIG. 1, in an optional form.

FIG. 3 is a schematic sectional view of an optional rear portion of the ruggedized case of FIG. 1, depicting how the rear portion includes a resilient portion that is molded over and through an inner rigid core.

FIG. 3A is a schematic perspective view of a rear portion of the ruggedized case of FIG. 3, depicting the construction of the rear portion.

FIG. 4 is a rear elevation view of the ruggedized case of FIG. 1.

FIG. 4A is a sectional view of the ruggedized case of FIG. 4, taken along view lines 4-4.

FIG. 5 is an end sectional view of the ruggedized case of FIG. 1.

FIG. 5A is a sectional view of the ruggedized case of FIG. 5, taken along view lines 5-5.

### DETAILED DESCRIPTION OF EXAMPLE EMBODIMENTS

The present invention may be understood more readily by reference to the following detailed description of the invention taken in connection with the accompanying drawing figures, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention. Any and all patents and other publications identified in this specification are incorporated by reference as though fully set forth herein.

Also, as used in the specification including the appended claims, the singular forms “a,” “an,” and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

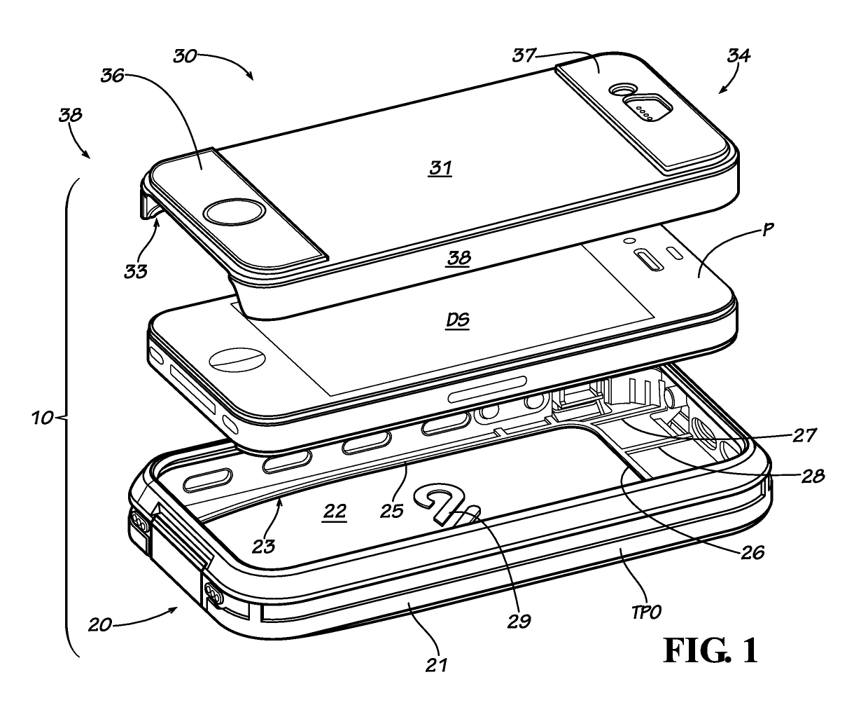

With reference now to the drawing figures, wherein like reference numbers represent corresponding parts throughout the several views, FIG. 1 shows a ruggedized case 10 for a hand-held electronic device of the type having a display screen. The particular hand-held electronic device P depicted is an Apple I-Phone®, but those skilled in the art will recognize that the invention can be utilized with a wide variety of hand-held electronic devices. The ruggedized case 10 includes a ruggedized main cover 20 adapted to be fitted closely over the hand-held electronic device P and to surround and protect the back, top side, bottom side, left side, and right side thereof. The ruggedized main cover 20 is open on one side thereof for receiving the hand-held electronic device therein. A substantially rigid screen protector 30 is provided for protecting the display screen DS of the hand-held electronic device P, and is adapted to be closely fitted over a front face of the hand-held electronic device P in a manner to overlay the display screen DS of the hand-held electronic device. Moreover, the substantially rigid screen protector 30 is adapted to be closely fitted within the ruggedized main cover 20 and held firmly therein in mating relationship. The substantially rigid screen protector 30 and the ruggedized main cover 20 are configured and adapted such that the screen protector 30 is to be first fitted over a front face of the hand-held electronic device P in a manner to overlay the display screen DS of the hand-held electronic device and then the screen protector 30 and the electronic device P together are closely fitted within the ruggedized main cover 20. This is depicted generally in FIG. 1. The substantially rigid screen protector 30 preferably is made from polycarbonate, a relatively hard and rigid material. However, due to the thinness of the screen protector 30, it can be flexed somewhat. Moreover, other materials can be used as desired.

The ruggedized case 10 is a two-piece construction in that it includes two main parts: a ruggedized main cover 20 and a screen protector 30. Moreover, the main cover 20 and a screen protector 30 preferably are each multi-layer, composite constructions which use materials of different properties married together to provide good protection for the hand-held electronic device P.

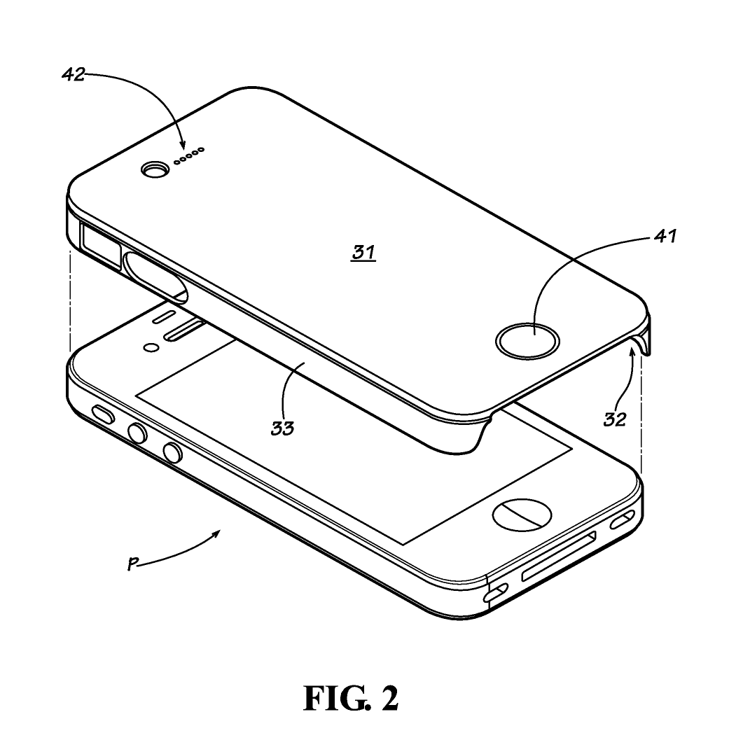

Optionally, the substantially rigid screen protector 30 includes a substantially rigid face panel 31 and at least two substantially rigid side panels 32, 33 extending from and connected to the face panel 31. Also optionally, the substantially rigid screen protector can include a pair of resilient protective pads 36, 37 positioned on upper and lower ends of an outer surface of the substantially rigid face panel 31. See FIG. 1. Optionally, if desired the substantially rigid screen protector 30 can be constructed without the pair of resilient protective pads positioned at upper and lower ends of an outer surface of the substantially rigid face panel 31. See FIG. 2.

As is well known in the art, the screen protector 30 can be provided with features to facilitate use of the electronic device without impeding such use. For example, the screen protector 30 can include a button hole or opening 41, a series 42 of holes for a microphone or speaker, etc.

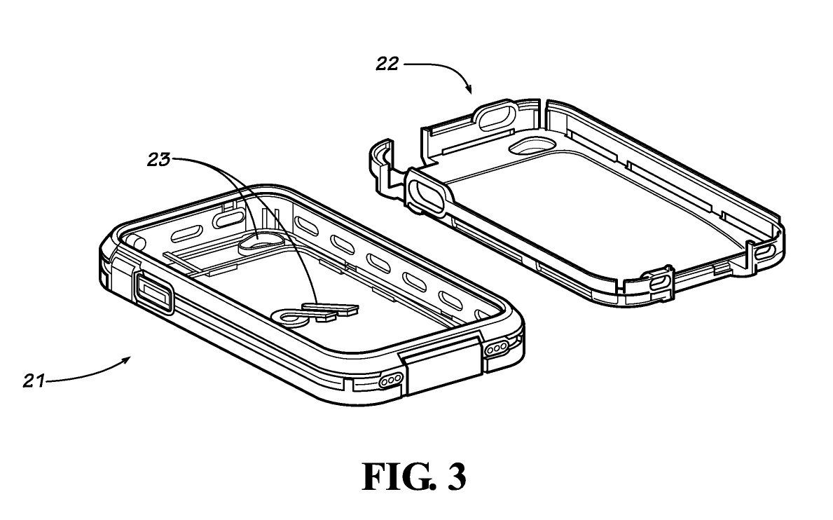

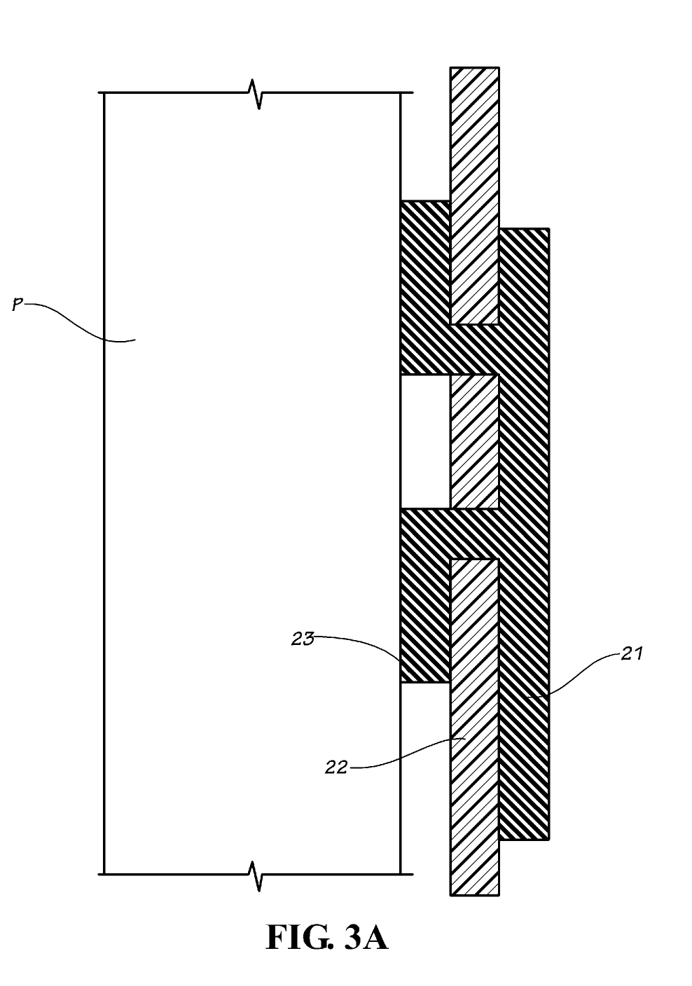

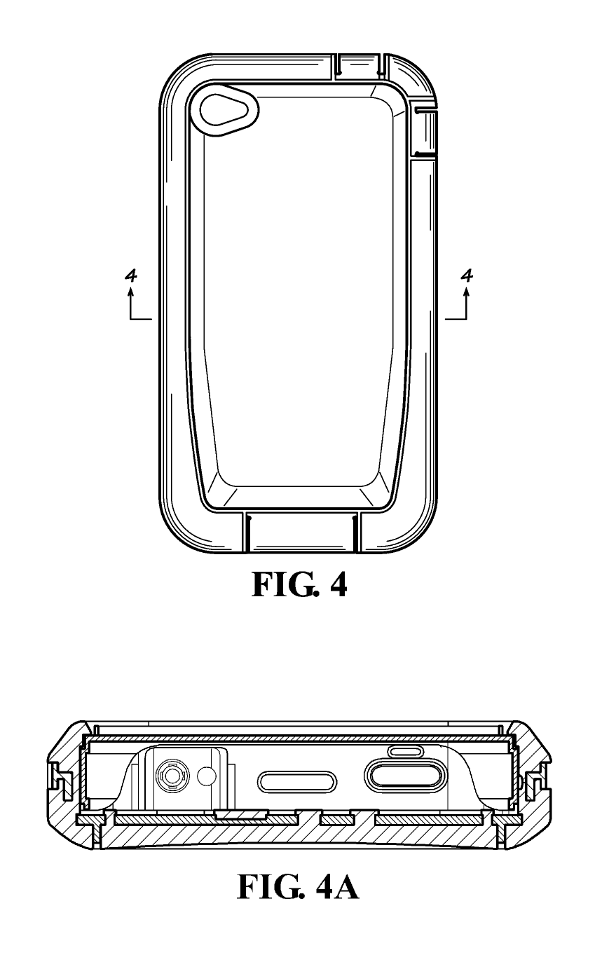

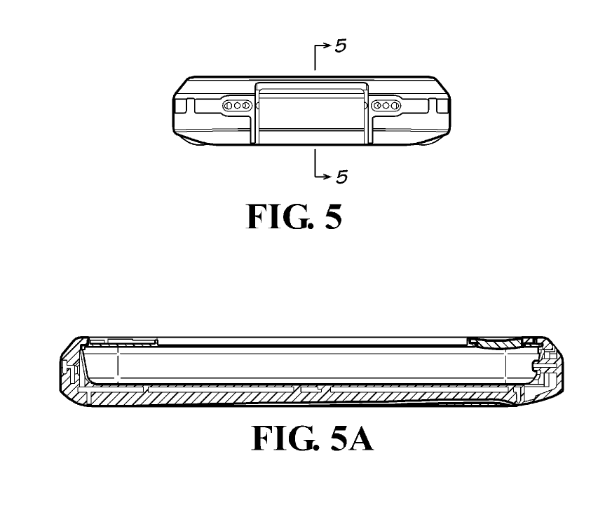

As shown in FIGS. 1 and 3, preferably the ruggedized main cover 20 includes a rigid protective tub 22, a resilient outer shell 21, and inner cushioning 23 molded at least partially through the rigid protective tub 22 and contiguous with the resilient outer shell 21 such that the rear panel portion of the substantially rigid protective tub 22 is substantially completely covered on one side by the resilient outer shell and on an opposite side of the substantially rigid protective tub one or more portions of the resilient inner cushioning is/are positioned between the substantially rigid protective tub and the hand-held electronic device inserted therein to cushion the hand-held electronic device P from the substantially rigid protective tub. See FIG. 1. Moreover, as shown in FIG. 3, both the rigid protective portion 22 and the resilient outer shell 21 are generally shallow tub-shaped elements with similar shapes and dimensions, and having a back and four sides extending therefrom (top, bottom, left, and right sides). This figure (FIG. 3) depicts the inner rigid part and the resilient outer part as separate pieces for illustration purposes only—the parts are not provided as separate pieces. Instead, the rigid inner protective portion 22 is first molded from a substantially rigid polymer, such as polycarbonate. Those skilled in the art will appreciate that a wide variety of materials can be used for this purpose. The rigid inner protective portion 22 is then placed in a mold and resilient material, such as TPE (thermoplastic elastomer), is molded onto, around, and through the rigid inner protective portion 22 to form a composite structure having TPE closely against the hand-held electronic device P, the rigid protective portion closely against the inner TPE, and having an outer layer of TPE closely against the rigid protective portion. The use of alternating layers of dissimilar materials is believed to assist in absorbing and distributing mechanical shock loads more widely, to better withstand severe mechanical shock forces.

The rigid outer shell 21 can be made from a variety of materials, such as polycarbonate (PC), ABS plastic, Nylon, polystyrene, etc, or a blend of various resins. The elastomeric portion of the outer case can be TPE, TPU, silicone, other soft elastomeric materials or the like. The screen protector can be made from PC, ABS, PMMA, or TPU. The soft portions of the screen protector can be silicone, TPE, TPU or other elastomeric materials.

As alluded to briefly above, once the rigid inner protective portion 22 is molded and cooled, it is placed into another mold for forming the resilient outer protective cushioning 21 and the resilient inner cushioning. Thus, the rigid inner portion 22 is used as an insert in the molding of the resilient inner and outer protective cushioning. The rigid inner portion 22 is provided with openings or passageways through which the hot liquid material of the resilient outer portion can flow during the molding of the resilient outer portion. In this way, the resilient material is molded onto the outside (backside) of the rigid inner portion and also onto the inside of the rigid inner portion. Thus, the substantially rigid protective tub 22 is substantially completely covered on one side (the back side) by the resilient outer shell and on an opposite side (the inside) of the substantially rigid protective tub several elements or portions of the resilient inner cushioning is/are positioned between the substantially rigid protective tub and the hand-held electronic device P inserted therein to cushion the hand-held electronic device P from the substantially rigid protective tub. Thus, soft resilient material is placed closely against the hand-held electronic device P, the rigid protective portion is closely against the inner soft cushioning, and an outer layer of soft cushioning material is closely against the rigid protective portion. In this way, the rigid protective panel is sandwiched between elements of soft, cushioning material. Also, the hand-held electronic device P is cradled by soft, cushioning elements, which in turn are backed up by the strong, rigid protective panels, and which in turn are themselves cushioned by more soft, cushioning elements. This composite, cushion-first construction provides superior protection for the device P against mechanical shock, such as occurs when the device P is dropped on a hard floor.

The several elements or portions of the resilient inner cushioning positioned between the substantially rigid protective tub 22 and the hand-held electronic device P inserted therein to cushion the hand-held electronic device P can take various forms. In the example shown in the drawing figures, the resilient inner cushioning is shown in the form of resilient ribs, such as ribs 25-28. Moreover, other resilient elements can be included, such as a resilient logo 29. Together, these resilient elements space the hand-held electronic device P from the substantially rigid protective tub and cushion it as well.

Thus, the substantially rigid protective tub is effectively sandwiched between a resilient outer shell molded around the substantially rigid protective tub and a resilient inner cushioning. As best seen in FIG. 3A, the resilient inner cushioning 23 can be molded at least partially through the rigid protective portion 22 and be contiguous with the resilient outer shell 21 such that the substantially rigid protective plate is substantially completely covered on one side by the resilient outer shell and on an opposite side of the substantially rigid protective plate one or more portions of the resilient inner cushioning is/are positioned between the substantially rigid protective plate.

Advantageously, the hand-held electronic device is cradled within a substantially rigid tub-like structure (albeit with elastomeric cushioning on the outside and inside thereof). Thus, the rear and all four sides of the hand-held electronic device are substantially armored with a hard shell protective panel. This provides a superior level of protection, particularly when augmented with the inner and outer resilient elements.

As is conventional in the art, the ruggedized case can be provided with movable flaps for covering and uncovering various ports, such as headphone ports, re-charging ports, 30-pin ports, etc. Also, the ruggedized case can be provided with raised buttons to activate various buttons in the hand-held electronic device. Moreover, openings can be formed in the ruggedized case for providing access to microphones, camera lenses, speakers, on/off switches, etc.

In use, the ruggedized case can be used as follows. First, the method comprises the steps of: a. providing a substantially rigid screen protector and a ruggedized main cover; b. placing the substantially rigid screen protector over a front face of the hand-held electronic device in a manner to overlay the display screen to secure the substantially rigid screen protector over the front face of the hand-held electronic device; and c. placing the substantially rigid screen protector together with the hand-held electronic device within the ruggedized cover to secure them therewithin. Thus, the screen protector 20 is first placed over the hand-held electronic device P and then the electronic device P and the screen protector 20 together are inserted into the main protective cover 30.

While the invention has been described with reference to preferred and example embodiments, it will be understood by those skilled in the art that a variety of modifications, additions and deletions are within the scope of the invention, as defined by the following claims.

What is claimed is:

1. A ruggedized case for a hand-held electronic device of the type having a display screen, the ruggedized case comprising:
a ruggedized main cover adapted to be fitted closely over the hand-held electronic device and to surround and protect the back, top side, bottom side, left side, and right side thereof, and wherein the ruggedized main cover is open on one side thereof for receiving the hand-held electronic device therein, wherein the ruggedized main cover includes a tub-like rigid portion and a resilient portion, the tub-like rigid portion including a substantially rigid back and substantially rigid top, bottom, left, and right sides, the resilient portion positioned on a plurality of the back and sides of the tub-like rigid portion; and
a substantially rigid screen protector for protecting the display screen of the hand-held electronic device, the substantially rigid screen protector being adapted to be closely fitted over a front face of the hand-held electronic device in a manner to overlay the display screen of the hand-held electronic device, the substantially rigid screen protector being adapted to be closely fitted within the ruggedized cover and held firmly therein, the substantially rigid screen protector having a substantially rigid transparent panel, and wherein the substantially rigid screen protector is adapted to be first fitted over a front face of the hand-held electronic device in a manner to overlay the display screen of the hand-held electronic device and then closely fitted within the ruggedized cover.

2. A ruggedized case for a hand-held electronic device as claimed in claim 1 wherein the substantially rigid screen protector includes a substantially rigid face panel and at least two substantially rigid side panels extending from and connected to the face panel.

3. A ruggedized case for a hand-held electronic device as claimed in claim 1 wherein the substantially rigid screen protector includes a pair of resilient protective pads positioned on upper and lower portions of an outer surface of the substantially rigid face panel.

4. A ruggedized case for a hand-held electronic device as claimed in claim 1 wherein the ruggedized main cover comprises a rigid protective plate, a resilient outer shell, and inner cushioning molded at least partially through the rigid protective plate and contiguous with the resilient outer shell such that the substantially rigid protective plate is substantially completely covered on one side by the resilient outer shell and on an opposite side of the substantially rigid protective plate one or more portions of the resilient inner cushioning is/are positioned between the substantially rigid protective plate and the hand-held electronic device inserted therein to cushion the hand-held electronic device from the substantially rigid protective plate.

5. A ruggedized case for a hand-held electronic device as claimed in claim 4 wherein the resilient inner cushioning includes resilient rib-like pads.

6. A ruggedized case for a hand-held electronic device as claimed in claim 4 wherein the resilient inner cushioning comprises cushioning pads in the shape of a company indicia.

7. A ruggedized case for a hand-held electronic device of the type having a display screen, the ruggedized case comprising:
a ruggedized cover adapted to be fitted closely over the hand-held electronic device and to surround and protect the back, top side, bottom side, left side, and right side thereof, and wherein the ruggedized cover is open on one side thereof for receiving the hand-held electronic device therein, the ruggedized cover comprising a substantially rigid protective portion sandwiched between a resilient outer shell molded around the substantially rigid protective portion and a resilient inner cushioning, the resilient inner cushioning being molded at least partially through the rigid protective portion and being contiguous with the resilient outer shell such that the substantially rigid protective portion is substantially completely covered on one side by the resilient outer shell and on an opposite side of the substantially rigid protective portion one or more portions of the resilient inner cushioning is/are positioned between the substantially rigid protective portion and the hand-held electronic device inserted therein to cushion the hand-held electronic device from the substantially rigid protective portion; and
a substantially rigid screen protector for protecting the display screen of the hand-held electronic device, the substantially rigid screen protector being adapted to be closely fitted over a front face of the hand-held electronic device in a manner to overlay the display screen of the hand-held electronic device, the substantially rigid screen protector being adapted to be closely fitted within the ruggedized cover and held firmly therein, the substantially rigid screen protector having a substantially rigid transparent panel and one or more resilient members adjacent an outer face of the transparent panel.

8. A ruggedized case for a hand-held electronic device as claimed in claim 7 wherein the substantially rigid screen protector includes a substantially rigid face panel and at least two substantially rigid side panels extending from and connected to the face panel.

9. A ruggedized case for a hand-held electronic device as claimed in claim 7 wherein the ruggedized cover and the screen protector are both generally tub-shaped.

10. A ruggedized case for a hand-held electronic device as claimed in claim 7, wherein the ruggedized cover includes a tub-like rigid portion and a resilient portion, the tub-like rigid portion including a substantially rigid back and substantially rigid top, bottom, left, and right sides, the resilient portion positioned on a plurality of the back and sides of the tub-like rigid portion.

11. A ruggedized case for a hand-held electronic device of the type having a display screen, the ruggedized case comprising:
a ruggedized, cushioned main cover adapted to be fitted closely over the hand-held electronic device and to surround and protect the back, top side, bottom side, left side, and right side thereof, and wherein the ruggedized, cushioned cover is open on one side thereof for receiving the hand-held electronic device therein, the ruggedized cover comprising a substantially rigid protective plate sandwiched between a resilient outer shell and a resilient inner cushioning; and
a substantially rigid screen protector for protecting the display screen of the hand-held electronic device, the substantially rigid screen protector being adapted to be closely fitted over a front face of the hand-held electronic device in a manner to overlay the display screen of the hand-held electronic device, the substantially rigid screen protector being adapted to be closely fitted within the ruggedized cover and held firmly therein, the substantially rigid screen protector having a substantially rigid transparent panel.

12. A ruggedized case for a hand-held electronic device as claimed in claim 11 wherein the substantially rigid screen protector includes a substantially rigid face panel and at least two substantially rigid side panels extending from and connected to the face panel.

13. A ruggedized case for a hand-held electronic device as claimed in claim 12 wherein the substantially rigid screen protector includes a pair of resilient protective pads positioned on upper and lower portions of an outer surface of the substantially rigid face panel.

14. A ruggedized case for a hand-held electronic device as claimed in claim 11 wherein the resilient inner cushioning is molded at least partially through the rigid protective plate and is contiguous with the resilient outer shell such that the substantially rigid protective plate is substantially completely covered on one side by the resilient outer shell and on an opposite side of the substantially rigid protective plate one or more portions of the resilient inner cushioning is/are positioned between the substantially rigid protective plate and the hand-held electronic device inserted therein to cushion the hand-held electronic device from the substantially rigid protective plate.

15. A ruggedized case for a hand-held electronic device as claimed in claim 11 wherein the resilient inner cushioning includes resilient rib-like pads.

16. A ruggedized case for a hand-held electronic device as claimed in claim 11 wherein the resilient inner cushioning comprises cushioning pads in the shape of a company indicia.

17. A ruggedized case for a hand-held electronic device as claimed in claim 11 wherein the substantially rigid screen protector snaps into the ruggedized, cushioned main cover.

18. A ruggedized case for a hand-held electronic device as claimed in claim 11 wherein the ruggedized main cover includes a tub-like rigid portion and a resilient portion, the tub-like rigid portion including a substantially rigid back and substantially rigid top, bottom, left, and right sides, the resilient portion positioned on a plurality of the back and sides of the tub-like rigid portion.

19. A ruggedized case for a hand-held electronic device of the type having a display screen, the ruggedized case comprising:
a ruggedized main cover adapted to be fitted closely over the hand-held electronic device and to surround and protect the back, top side, bottom side, left side, and right side thereof, and wherein the ruggedized main cover is substantially tub-shaped and is open on one side thereof for receiving the hand-held electronic device therein, the ruggedized main cover comprising a substantially rigid back and four substantially rigid sides extending up from the back, the ruggedized main cover further comprising a resilient portion; and
a substantially rigid screen protector for protecting the display screen of the hand-held electronic device, the substantially rigid screen protector being adapted to be closely fitted over a front face of the hand-held electronic device in a manner to overlay the display screen of the hand-held electronic device, the substantially rigid screen protector being adapted to be closely fitted within the ruggedized main cover and held firmly therein, the substantially rigid screen protector having a substantially rigid transparent panel and one or more resilient members adjacent an outer face of the transparent panel.

20. A ruggedized case for a hand-held electronic device as claimed in claim 19 wherein the resilient portion of the ruggedized main cover comprises a resilient outer shell and a resilient inner cushioning, with the substantially rigid back and four substantially rigid sides extending up from the back being sandwiched between the resilient outer shell and the resilient inner cushioning.

21. A ruggedized case for a hand-held electronic device of the type having a display screen, the ruggedized case comprising:
a ruggedized main cover adapted to be fitted closely over the hand-held electronic device and to surround and protect the back, top side, bottom side, left side, and right side thereof, and wherein the ruggedized main cover is substantially tub-shaped and is open on one side thereof for receiving the hand-held electronic device therein, the ruggedized main cover comprising a substantially rigid back and four substantially rigid sides extending up from the back, the ruggedized main cover further comprising resilient portion on the inside and outside of the substantially rigid back, whereby the hand-held electronic device is cradled by soft, cushioning elements, which in turn are backed up by the substantially rigid back, and which in turn is cushioned by more soft, cushioning elements.

22. A method of protecting a hand-held electronic device of the type having a display screen, the method comprising the steps of:
providing a substantially rigid screen protector and a ruggedized main cover;
placing the substantially rigid screen protector over a front face of the hand-held electronic device in a manner to overlay the display screen to secure the substantially rigid screen protector over the front face of the hand-held electronic device; and
placing the substantially rigid screen protector together with the hand-held electronic device within the ruggedized cover to secure them therewithin.
